(19) United States
(12) Patent Application Publication
(10) Pub. No.: US 2014/0050847 A1
(43) Pub. Date: Feb. 20, 2014

(54) DEPOSITION DEVICE AND DEPOSITION METHOD USING JOULE HEATING

(71) Applicants: Jae-Sang RO, Seoul (KR); Won-Eui Hong, Seoul (KR); Seog-Young Lee, Seoul (KR); Ingoo Jang, Seoul (KR)

(72) Inventors: Jae-Sang RO, Seoul (KR); Won-Eui Hong, Seoul (KR); Seog-Young Lee, Seoul (KR); Ingoo Jang, Seoul (KR)

(73) Assignee: EnSilTech Corporation, Seoul (KR)

(21) Appl. No.: 13/589,508

(22) Filed: Aug. 20, 2012

(51) Int. Cl. C23C 16/448; C23C 16/52; C23C 16/458

(52) U.S. Cl. 427/248.1; 118/726; 118/712

(57) ABSTRACT

Provided are a deposition method of patterning a thin film on a substrate using momentary Joule heating in a vacuum environment, and a method thereof. The deposition device forms a deposition target layer on one surface of a source substrate as a pattern to be deposited. A deposition target layer forming unit forms a deposition target layer on the one surface of the source substrate to cover the conductive layer. A chamber in a vacuum state receives the source substrate on which the conductive layer and the deposition target layer are formed and the target substrate. A target substrate is disposed in the chamber to face the source substrate. A power supply applies power to the conductive layer to heat-generate the conductive layer. A configuration of the deposition device is very simple, and it is easy to uniformly form a deposition thickness.

### BACKGROUND OF THE INVENTION

1. Field of the Invention

The disclosure relates to a deposition device and a deposition method using Joule heating, and more particularly, to a deposition method of patterning a thin film on a substrate using momentary Joule heating in a vacuum environment, and a method thereof.

2. Description of the Related Art

A deposition process is performed in a fabricating process of a semiconductor device and a fabricating process of a display.

That is, the fabricating process includes a process of depositing metal such as titanium (Ti), tungsten (W), aluminum (Al), or copper (Cu). Further, a fabricating process of a flat panel display includes a process of depositing an organic material or an inorganic material. There are a Plasma Display Panel (PDP) and a Field Emission Display (FED) as examples of a device using the in the organic material. There are a Liquid Crystal Display (LCD) and an Organic Light Emitting Diode (OLED) as examples of a device using the organic material.

A deposition method is classified into chemical vapor Deposition (CVD) and physical vapor deposition (PVD). The CVD uses chemical reaction and the PVD uses a physical device, and each of the CVD and the PVD includes thermal evaporation, ion-plating, and sputtering. Such a deposition method may be selectively used according to a type of a deposition target and a condition of a process, and respective methods need different deposition devices.

FIG. 1 is a schematic view illustrating a configuration of a deposition device according to the related art. As shown in FIG. 1, the deposition device includes a chamber 110 in which a vacuum is formed, a crucible 120 disposed at a lower portion of the chamber 110 and receiving a deposition target 121, a substrate 130 adhering to a surface of the deposition target 121 evaporated by heating the crucible 120, and a shadow mask 140 disposed between the substrate 130 and the crucible 120 and exposing a part of the substrate 130 to be deposited.

However, the deposition device according to the related art is disadvantageous in that it is difficult to uniformly form a deposition thickness of the substrate because a deposition target is evaporated from the crucible is not uniformly diffused. To solve such a problem, it may be used that a method of controlling an exposing time of the substrate to the crucible by installing a separate shutter in the chamber. Accordingly, there is a problem in that a configuration of the deposition device is complicated and manufacturing cost is increased.

Further, the deposition method according to the related art has a disadvantage in that a shadow mask is transformed due to heat in the chamber or a deposition target is not easily separated. Accordingly, there is a problem in that the shadow mask should frequently be replaced or the shadow mask should always be cleaned.

Further, the deposition method according to the relate art has following disadvantages. That is, an organic material is deposited and deteriorated in a deposition chamber to have a non-uniform thickness, a post process is advanced. Accordingly, a bad deposition substrate is performed to a post process and is discarded afterward so that a yield is bad, a total process cost is increased and a process time is long because a process of the bad substrate is continuously performed.

Current AMOLED panel manufacturing businesses perform an RGB color patterning in a vacuum deposition scheme using the Fine Metal Mask (FMM) in a process of manufacturing a patterned organic film formed by an RGB emission layer. However, such a scheme has a problem in that deposition of an organic film having a high resolution is impossible based on a resolution limit of an FMM itself and a shadow effect of a shadow mask during deposition and deposition of an organic film corresponding to a large area glass substrate is impossible due to a drooping by a gravity as the size of the FMM configured by a metal plate is increased.

### SUMMARY OF THE INVENTION

The present invention has been made in view of the above problems, and provides a deposition device capable of uniformly depositing a deposition target on a substrate, and simplifying a configuration without using a crucible and a shadow mask, and a deposition method thereof.

The present invention further provides a deposition device using Joule heating which may sense inferiority during deposition to increase a yield not to advance a post process and to reduce a process cost and a total process time.

In accordance with an aspect of the present invention, a deposition device using Joule heating, includes: a source substrate fixture fixing a source substrate, a conductive layer being formed on one surface of the source substrate with a pattern to be deposited; a deposition target layer forming unit for forming a deposition target layer on the one surface of the source substrate to cover the conductive layer; a target substrate fixture disposed to face the source substrate fixture and fixing a target substrate; a power supply for applying power to the conductive layer to heat-generate the conductive layer; and a chamber in a vacuum state for receiving the source substrate on which the conductive layer and the deposition target layer are formed and the target substrate.

The source substrate and the target substrate may be disposed in the vicinity of each other by leas than several tens μm.

The deposition device may further include a resistance measuring unit provided in one side of the deposition device to be electrically connected to the conductive layer.

The deposition device may further include a heat generation temperature measuring unit provided in one side of the deposition device and measuring a heat generation temperature of the conductive layer.

The deposition device may further include a source substrate cleaner.

In accordance with another aspect of the present invention, a deposition method using Joule heating, includes: forming a deposition target layer on the one surface of the source substrate to cover the conductive layer, a conductive layer being formed on one surface of the source substrate as a pattern to be deposited; fixing the source substrate to a source substrate fixture, and fixing the target substrate to a target substrate fixture, and disposing the target substrate fixture and the source substrate fixture while facing the target substrate fixture and the source substrate fixture; applying power to the conductive layer to heat-generate the conductive layer; and evaporating and depositing a deposition target layer located at one surface of the conductive layer facing the target substrate to the target substrate by heat-generating the conductive layer.

The source substrate and the target substrate may be disposed to face the source substrate and the target substrate in a chamber in a vacuum state.

The method may further electrically connect the conductive layer and a resistance measuring unit to each other to measure resistance of the conductive layer before the applying power to the conductive layer.

The method may further include measuring a heat generation temperature of the conductive layer when the applying power to the conductive layer to heat-generate the conductive layer.

The method may further include moving the source substrate to a source substrate cleaner to clean an organic material remaining on the source substrate after the evaporating and depositing of the deposition target layer.

The method may further includes forming a deposition target layer on one surface of the cleaned source substrate after cleaning the organic material remaining on the source substrate; fixing the source substrate to a source substrate fixture, fixing the target substrate to a target substrate fixture, disposing the source substrate fixture and the target substrate to a target substrate fixture to face each other; applying power to the conductive layer to heat-generate the conductive layer; and evaporating and depositing a deposition target layer located at one surface of the conductive layer facing the target substrate to the target substrate by heat-generating the conductive layer.

Accordingly, a configuration of the deposition device is very simple, and it is easy to uniformly form a deposition thickness.

A time required for a deposition process can be reduced using momentary heat generation of high temperature of a conductive layer in a deposition process.

Further, since a conductive layer is connected to a resistance measuring unit in a deposition device before applying electric field to the conductive layer and the resistance measuring unit measures resistance and determines presence of damage of a conductive layer pattern and whether there is a contact inferiority of the conductive layer and an electrode for applying electric field, the inferiority may be checked before advancing the process and a yield is improved. Since an unnecessary process is not performed, a process cost and time may be reduced.

Heat generation temperature of a conductive layer is measured during applying electric field and luminance and efficiency of a device substrate are compared after performing a post process to search an optimal heat generation temperature, thereby optimizing a process.

Further, in the present invention, since a used source substrate may not be discarded but may be reused, a process cost can be reduced.

### BRIEF DESCRIPTION OF THE DRAWINGS

The objects, features and advantages of the present invention will be more apparent from the following detailed description in conjunction with the accompanying drawings, in which:

FIG. 1 is a schematic view illustrating a configuration of a deposition device according to the related art;

FIG. 2 is a block diagram illustrating a schematic configuration of a deposition device using Joule heating according to an exemplary embodiment of the present invention;

FIG. 3 is a cross-section enlarged view illustrating a source substrate and a target substrate according to a first embodiment of the present invention;

FIG. 4 is a block diagram illustrating a schematic configuration of a deposition device using Joule heating according to a second embodiment of the present invention;

FIG. 5 is a block diagram illustrating a schematic configuration of a deposition device using Joule heating according to a third embodiment of the present invention;

FIG. 6 is a block diagram illustrating a schematic configuration of a deposition device using Joule heating according to a fourth embodiment of the present invention;

FIGS. 7A and 7B are views illustrating a deposition procedure according to an exemplary embodiment of the present invention;

FIG. 8 is a block diagram illustrating a schematic configuration of a deposition device using Joule heating according to a modified example of FIG. 2;

FIG. 9 is a block diagram illustrating a schematic configuration of a deposition device using Joule heating according to a modified example of FIG. 4;

FIG. 10 is a block diagram illustrating a schematic configuration of a deposition device using Joule heating according to a modified example of FIG. 5;

FIG. 11 is a block diagram illustrating a schematic configuration of a deposition device using Joule heating according to a modified example of FIG. 6;

FIG. 12 is a flowchart illustrating a deposition method using Joule heating according to a first embodiment of the present invention;

FIG. 13 is a flowchart illustrating a deposition method using Joule heating according to a second embodiment of the present invention;

FIG. 14 is a flowchart illustrating a deposition method using Joule heating according to a third embodiment of the present invention; and

FIG. 15 is a flowchart illustrating a deposition method using Joule heating according to a fourth embodiment of the present invention.

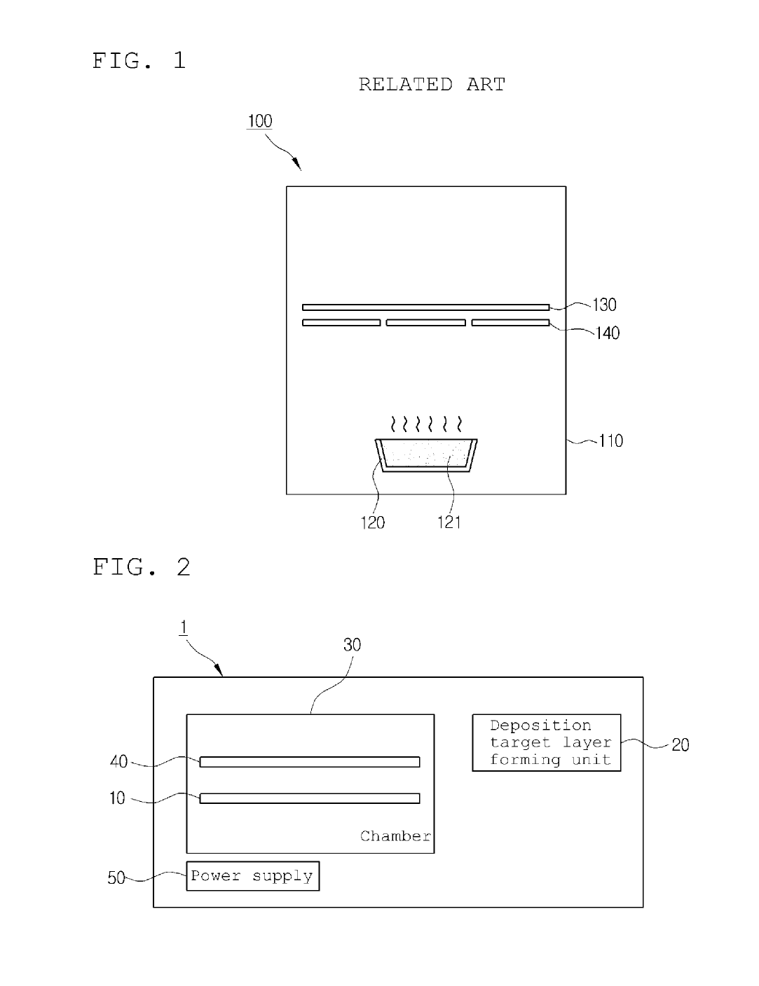

### DETAILED DESCRIPTION OF EXEMPLARY EMBODIMENTS

Exemplary embodiments of the present invention are described with reference to the accompanying drawings in detail. The same reference numbers are used throughout the drawings to refer to the same or like parts. Detailed descriptions of well-known functions and structures incorporated herein may be omitted to avoid obscuring the subject matter of the present invention.

Hereinafter, a technical configuration of a deposition device using Joule heating will be described with respect to accompanying drawings in detail.

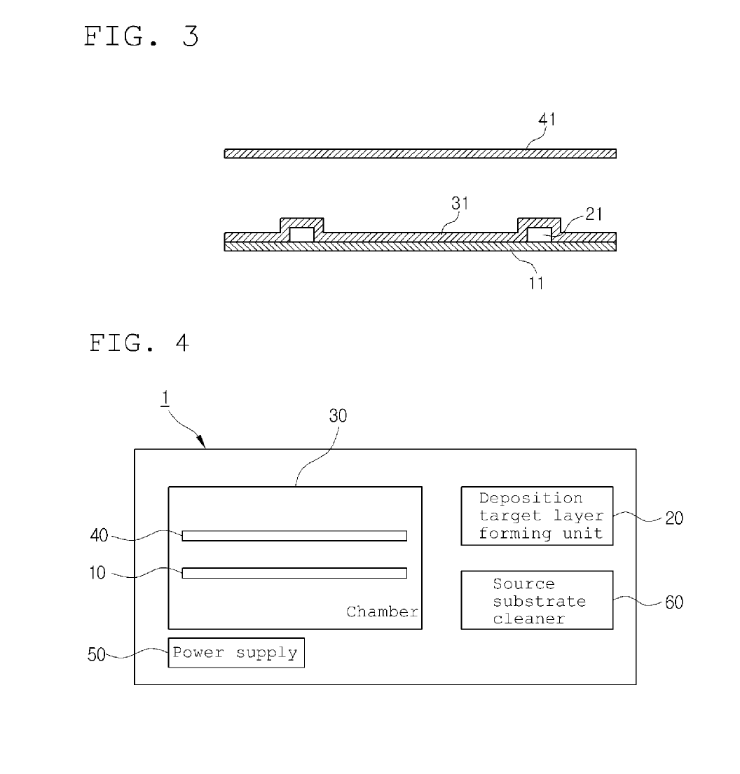

FIG. 2 is a block diagram illustrating a schematic configuration of a deposition device using Joule heating according to an exemplary embodiment of the present invention, and FIG. 3 is a cross-section enlarged view illustrating a source substrate and a target substrate according to a first embodiment of the present invention.

As shown in FIGS. 2 and 3, a deposition device 1 includes a source substrate fixture 10, a deposition target layer forming unit 20, a chamber 30, a target substrate fixture 40, and a power supply 50.

The source substrate fixture 10 and the target substrate fixture 40 fix a source substrate 11 and a target substrate 41, respectively, and may use an EMC chuck or a robot arms.

In this case, the source substrate 11 may use an insulating material.

Meanwhile, a conductive layer 21 is formed on one surface of the source substrate 11. In this case, the conductive layer 21 is formed to have a pattern to be deposited. The conductive layer 21 is preferably made from molybdenum (Mo), or chrome (Cr), tungsten (W). The conductive layer 21 receives power and is heated by resistance heat.

The deposition target layer forming unit 20 forms a deposition target layer 31 on one surface of the source substrate 11. The deposition target layer 31 may be formed on an entire surface of the source substrate 11 to cover the conductive layer 21. The deposition target layer 31 may be made from a raw material of deposition such as an organic material, an inorganic material, or metal. The deposition target layer forming unit 20 may be a certain configuration capable of forming the deposition target layer 31 on the source substrate 11.

For example, the deposition target layer forming unit 20 may form the deposition target layer 31 on the source substrate 11 by a deposition method. In this case, the deposition target layer forming unit 20 has a configuration of a coating device.

Vacuum is formed inside the chamber 30, and the chamber 30 receives the source substrate 11 in which the conductive layer 21 and the deposition target layer 31 are formed.

The target substrate fixture 40 fixes a target substrate 41, and is disposed in the chamber 30 to face a source substrate fixture 10. Accordingly, the target substrate 41 is disposed to face the deposition target layer 31 formed on the source substrate 11.

In this case, the target substrate 41 is preferably disposed in the vicinity of the source substrate 11 by less than several tens μm.

The power supply 50 is connected to the conductive layer 21 and applies power. The conductive layer 21 having received the power from the power supply 50 momentarily generates heat and becomes a high temperature.

FIG. 4 is a block diagram illustrating a schematic configuration of a deposition device using Joule heating according to a second embodiment of the present invention.

Referring to FIG. 4, the deposition device using Joule heating of the present invention may further include a source substrate cleaner 60.

As described above, when the deposition target layer 31 is evaporated, transferred to the target substrate 41, and deposited due to heat generation of the conductive layer 21 formed on the source substrate 11, a residual deposition target layer without being transferred remains on the source substrate 11.

In this case, the source substrate whose deposition procedure is terminated is not discarded as it is but is conveyed to the source substrate cleaner 60, and completely cleans the deposition target layer 31 remaining from the source substrate cleaner 60.

As described above, the source substrate 11 in which the remaining deposition target layer 31 is cleaned is again conveyed to the deposition target layer forming unit 20 of the deposition device according to the present invention. After that, when the deposition target layer 31 is again formed on the source substrate 11, the source substrate 11 on which the deposition target layer 31 is conveyed into the chamber 30, and the source substrate 11 is fixed by the source substrate fixture 10, faces the target substrate fixed by the target substrate fixture 40, and the deposition target layer 31 is evaporated and transferred on the target substrate 41 by Joule heating, the source substrate 11 is again conveyed to the source substrate cleaner 60.

Accordingly, since the present invention may repeat the foregoing process, the source substrate 11 on which the conductive layer is formed can be permanently used without being discarded.

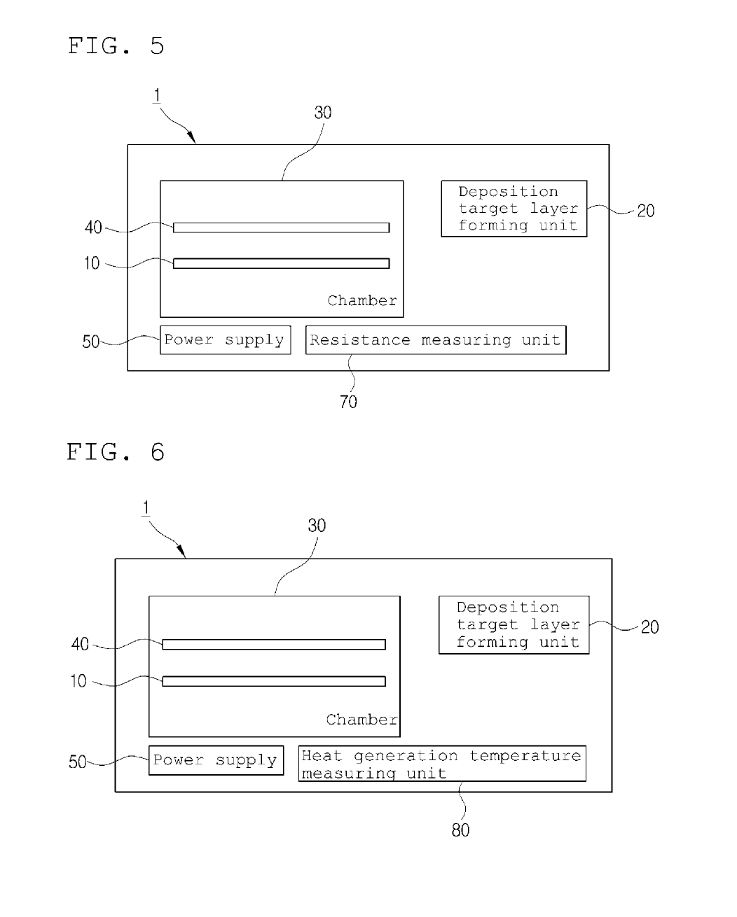

FIG. 5 is a block diagram illustrating a schematic configuration of a deposition device using Joule heating according to a third embodiment of the present invention.

As shown in FIG. 5, a resistance measuring unit 70 may be provided at one side of the deposition device using Joule heating according to the present invention. The resistance measuring unit is electrically connected to the conductive layer 21 and measures resistance of the conductive layer 21.

Accordingly, in the present invention, the conductive layer 21 is electrically connected to the resistance measuring unit 70, and the resistance measuring unit 70 may measure resistance of the conductive layer 21 to determine whether an electrode applying an electric field contacts with the conductive layer. Further, it is determined whether the conductive layer 21 pattern is damaged. When resistance of the source substrate is beyond a normal range before applying an electric field, the source substrate is previously replaced and a process is advanced, thereby improving a yield. When inferiority occurs, because an addition process is not advanced, a process cost can be reduced.

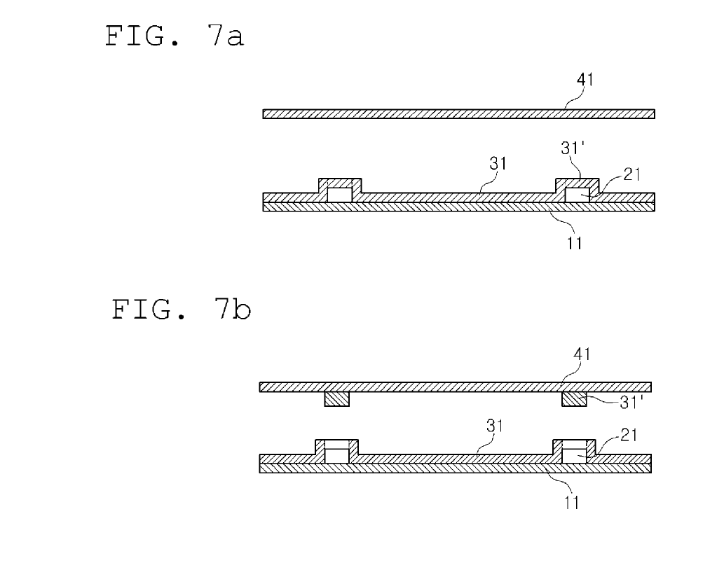

FIG. 6 is a block diagram illustrating a schematic configuration of a deposition device using Joule heating according to a fourth embodiment of the present invention.

As shown in FIG. 6, a heat generation temperature measuring unit 80 of a conductive layer may be further provided at one side of the deposition device using Joule heating according to the present invention.

The heat generation temperature measuring unit 80 measures a heat generation temperature when an electric field is applied to the conductive layer 21. After that, after advancing a post process, because luminance and efficiency of a device panel being a target substrate are compared to search an optimal heat generation temperature and a process condition is again controlled, a process can be advanced with an optimal process condition.

Meanwhile, although this embodiment has illustrated a configuration of adding a heat generation temperature measuring unit to a configuration of FIG. 3, a third embodiment shown in FIG. 5 may further include the heat generation temperature measuring unit.

Further, the present invention may further include a resistance measuring unit and/or a heat generation temperature measuring unit in addition to a configuration of FIG. 4.

FIGS. 7A and 7B are views illustrating a deposition procedure according to an exemplary embodiment of the present invention.

As shown in FIG. 7A, a target substrate 41 is disposed to face the source substrate 11. In FIG. 7A, although the target substrate 41 is disposed at an upper portion of the source substrate 11, the two substrates 11 and 41 may be disposed parallel to each other in a vertically upright state, or upper and lower locations of the two substrates may be changed.

The conductive layer 21 is formed on an upper surface of the source substrate 11 with a pattern to be deposited. Moreover, a deposition target layer 31 is formed on an upper surface of the conductive layer 21. If power is applied to the conductive layer 21, the conductive layer 21 is heated at a high temperature by resistance heat. A deposition target layer 31′ disposed on an upper vertical surface of the conductive layer 21 is evaporated by heating the conductive layer 21.

As shown in FIG. 7B, the evaporated deposition target layer 31′ is diffused under vacuum atmosphere. The diffused deposition target layer 31′ is deposited on a lower surface of a target substrate 41 which is disposed close to an upper portion of the source substrate 11. Because the deposition target layer 31′ evaporated in a vacuum state is diffused with a straight property, a deposition target layer 31′ is deposited on the target substrate 41 with a pattern of the conductive layer 21. Accordingly, a deposition target may be formed on the target substrate 41 with a pattern to be deposited.

In summary, a deposition device 1 using Joule heating uses a source substrate 11 to form a pattern for deposition on the target substrate 41. The conductive layer 21 is formed on the source substrate as a pattern to be deposited, and a deposition target layer 21 is formed on the conductive layer 21 in the form of a thin film.

In this case, an operation of forming the conductive layer 21 on the source substrate 11 and an operation of forming the deposition target layer 31 on the conductive layer 21 may be easily performed. That is because the deposition device 1 using Joule heating needs not a crucible for heating a deposition target and a shadow mask for forming a pattern for deposition on the target substrate.

Accordingly, the deposition device 1 using Joule heating may be configured by a very simple structure.

Further, the deposition target layer 31 may be easily coated or deposited on the source substrate 11 using various coating method or deposition methods. In this case, the deposition target layer 31 may be formed on the source substrate 11 to have an uniform thickness. Accordingly, the thickness of the deposition target layer 31 deposited on the target substrate 41 becomes uniform.

FIG. 8 is a block diagram illustrating a schematic configuration of a deposition device using Joule heating according to a modified example of FIG. 2.

As shown in FIG. 8, a deposition target layer forming unit 20 may be provided inside a chamber 30. That is, the deposition target layer 31 may be formed on the source substrate 11 on which the conductive layer is formed in a single chamber 30.

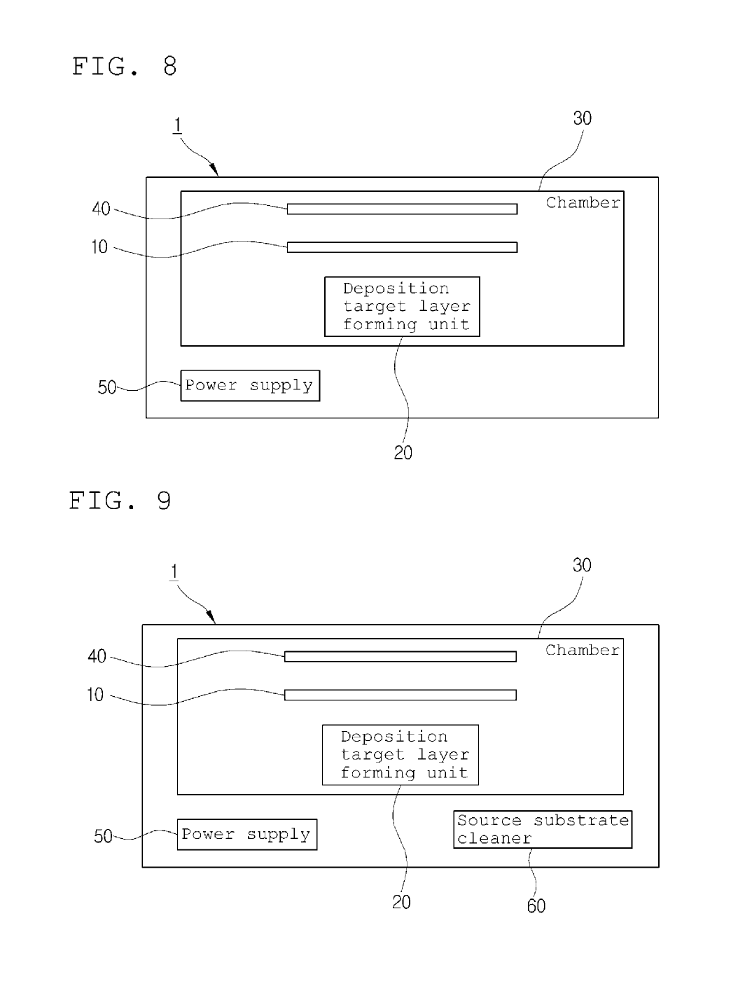

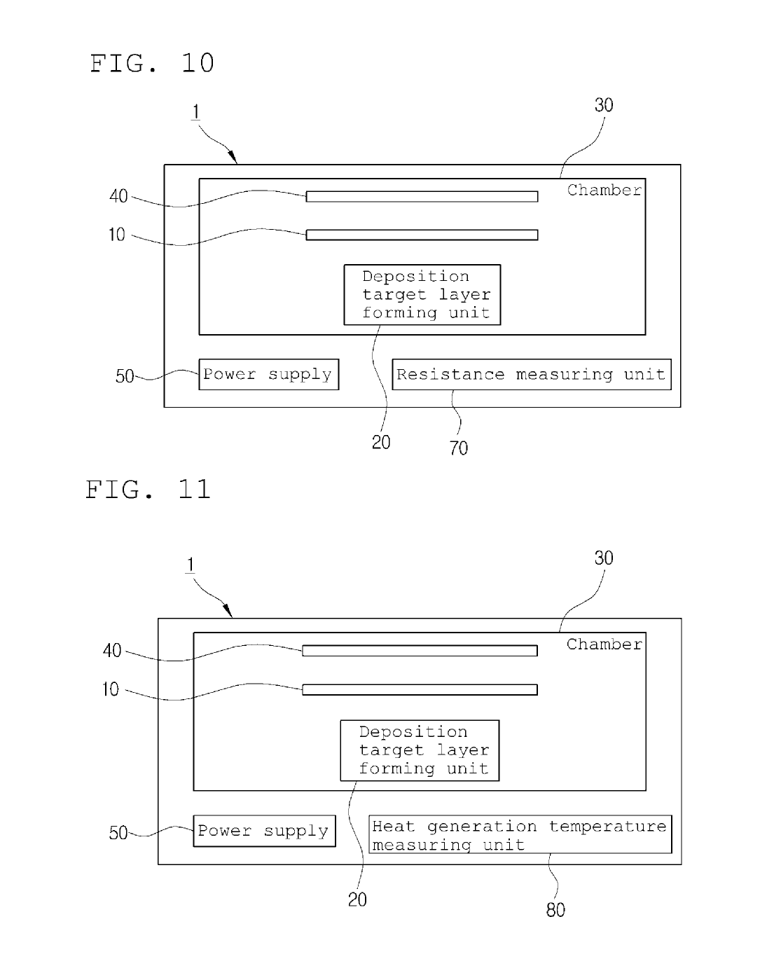

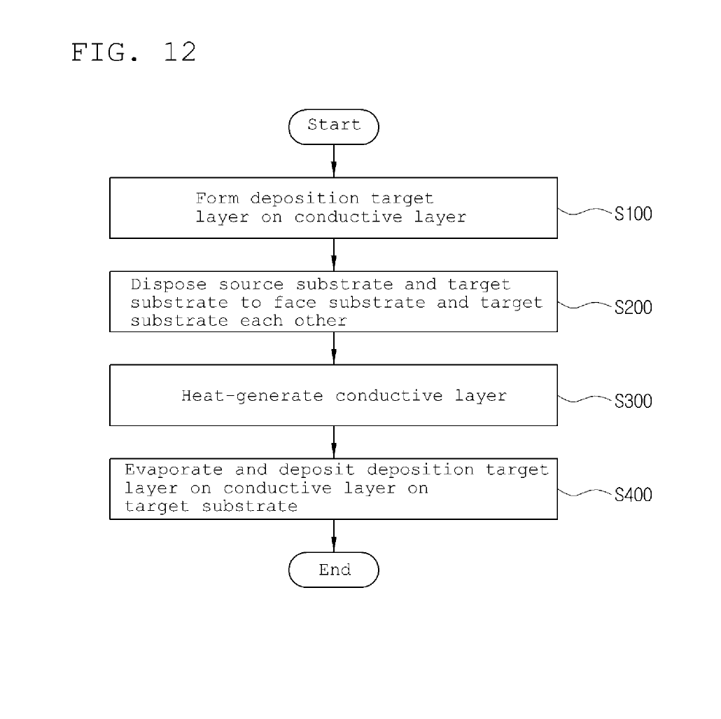

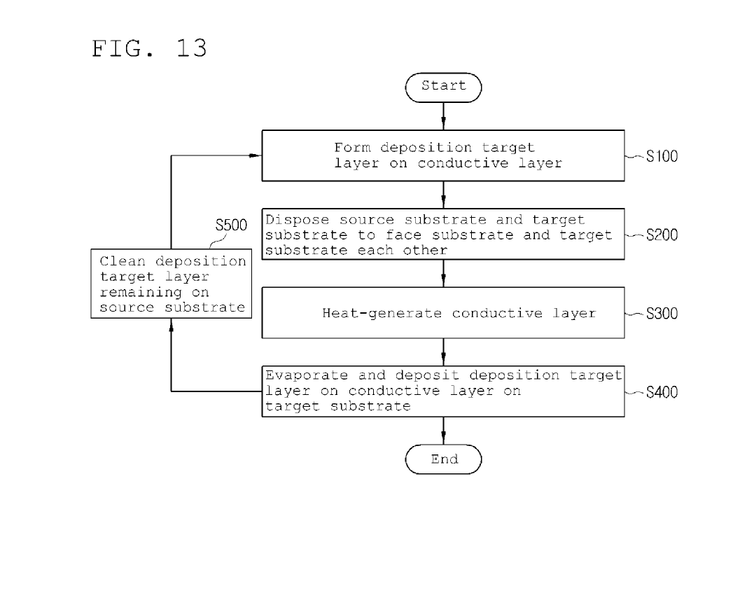

FIGS. 9 to 11 are block diagrams illustrating schematic configurations of deposition devices using Joule heating according to modified examples of FIGS. 4 to 6, respectively.

As shown in FIGS. 9 to 11, in the modified examples, a deposition target layer forming unit 20 may be provided in a chamber 30.

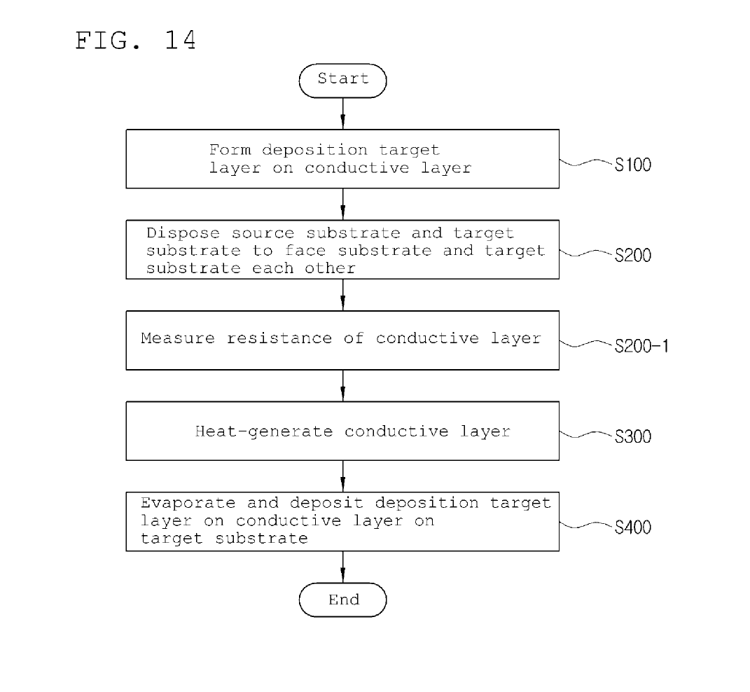

FIG. 12 is a flowchart illustrating a deposition method using Joule heating according to a first embodiment of the present invention.

As shown in FIG. 12, a deposition method using Joule heating includes forming a deposition target layer 31 on a source substrate 11 having a conductive layer formed on one surface of the source substrate 11 (S100), disposing the source substrate 11 and a target substrate 41 to face the source substrate 11 and the target substrate 41 each other (S200), heat-generating the conductive layer (S300), and evaporating and depositing the deposition target layer 31 on the target substrate 41 (S400).

Referring to FIGS. 2 and 3, Step S100 is a step of forming a deposition target layer 31 on one surface of a source substrate 11 on which a conductive layer is formed. The deposition target layer 31 completely covers the conductive layer 21 which is formed on one surface of the source substrate 11.

Step S200 disposes the source substrate 11 and the target substrate 41 to face the source substrate 11 and the target substrate 41 in a chamber 30 in a vacuum state. That is, after the conductively layer 21 and the deposition target layer 31 are formed on the source substrate 11 outside the chamber 30, the source substrate 11 and the target substrate 41 may be disposed to face each other and be loaded into the chamber 30. Further, after the conductive layer 21 and the deposition target layer 31 are formed on the source substrate 11 outside the chamber 30, only the source substrate 11 may be loaded toward the target substrate 41 disposed in the chamber 30.

Further, after the conductive layer 21 is formed on the source substrate 11 outside the chamber 30, the source substrate 11 is loaded into the chamber 30 and the deposition target layer 31 is formed on the source substrate 11 in the chamber 30, the source substrate 11 and the target substrate 41 may be disposed to face source substrate 11 and the target substrate 41. In addition, conveyance of the source substrate 11 and the target substrate 41 may be implemented in various schemes.

Step S300 applies power to the conductive layer 21. Supply of the power may be achieved by the power supply 50. The conductive layer 21 to which the power is applied is heated at a high temperature within a short time. For example, if power of several tens kw/cm² is supplied to the conductive layer 21 for several μs to several hundreds μs, the conductive layer 21 may be momentarily heat-generated at a temperature greater than 1000° C. As another embodiment, a supply time of power may be set to the range of several hundreds μs to several ms, and a reach temperature of the conductive layer 21 may be set to the range of 400° C. to 800° C.

Step S400 deposits the deposition target layer 31 on the target substrate 41. That is, when the conductive layer 21 is heat-generated, the deposition target layer 31 disposed at one surface of the conductive layer 21, namely, one surface of the conductive layer 21 facing the target substrate 41 is evaporated. After that, the evaporated deposited target layer 31 is diffused into the chamber 30 in a vacuum state and is deposited on the target substrate 41.

Further, in the second embodiment of the present invention, as shown in FIGS. 4 and 12, a deposition target layer 31 on the conductive layer 21 is evaporated and is deposited on the target substrate 41, the source substrate 11 on which a residual deposition target layer 31 remains is conveyed to a source substrate cleaner 60, and the source substrate cleaner 60 completely cleans and removes the deposition target layer 31 remaining on the source substrate 11 (S500).

The conductive layer 21 is formed on the cleaned source substrate 11, and the source substrate 11 on which a residual deposition target layer is cleaned is again conveyed to a deposition target layer forming unit 20 of the deposition device according to the present invention. After that, the deposition target layer 31 is again formed on the source substrate 11, the source substrate 11 on which the deposition target layer 31 is formed is conveyed into the chamber 30, is fixed by the source substrate fixture 10, faces the target substrate 41, and a deposition target layer 31 is evaporated on the target substrate 41 and formed on the target substrate 41.

After that, the source substrate 11 is again conveyed to the source substrate cleaner 60 and the foregoing process is repeatedly performed.

Accordingly, in the present invention, since a source substrate 11 on which the deposition target layer 31 remains is not discarded as it is after completion of the process, but may be semi-permanently used, a process cost is reduced.

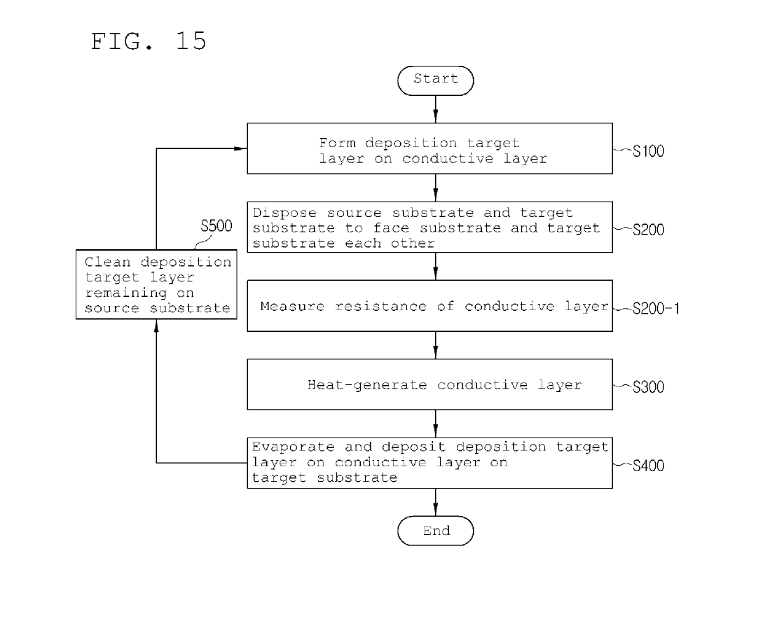

Further, in the third embodiment of the present invention, as shown in FIGS. 6 and 14, the conductive layer and a resistance measuring unit are electrically connected to each other and the resistance measuring unit measures resistance of the conductive layer (S200-1) before heat-generating the conductive layer by applying power to the conductive layer.

Further, in the fourth embodiment of the present invention, as shown in FIG. 15, the used source substrate 11 is conveyed to the source substrate cleaner 60, a remaining deposition target layer 31 is removed and the source substrate 11 may be again used in the process.

Further, in the fifth to eighth embodiments of the present invention, when power is applied to the conductive layer to heat-generate the conductive layer in the first to fourth embodiments, a heat generation temperature of the conductive layer may be measured by a heat generation measuring unit.

In the deposition method using Joule heating, because a step of heating a crucible in a chamber is not necessary, a time required for a deposition process may be reduced. A conductive layer and a deposition target layer may be easily formed on the source substrate, so that a large capacity deposition process may be performed while loading and unloading the source substrate and the target substrate into the chamber. Therefore, a deposition method using Joule heating is suitable in mass production.

Although a deposition device and method using Joule heating according to exemplary embodiments of the present invention have been described in detail hereinabove, it should be clearly understood that many variations and modifications of the basic inventive concepts herein taught which may appear to those skilled in the present art will still fall within the spirit and scope of the present invention, as defined in the appended claims.

What is claimed is:

1. A deposition device using Joule heating, comprising:
a source substrate fixture for fixing a source substrate, a conductive layer being formed on one surface of the source substrate with a pattern to be deposited;
a deposition target layer forming unit for forming a deposition target layer on the one surface of the source substrate to cover the conductive layer;
a target substrate fixture disposed to face the source substrate fixture and for fixing a target substrate;
a power supply for applying power to the conductive layer to heat-generate the conductive layer; and
a chamber in a vacuum state for receiving the source substrate on which the conductive layer and the deposition target layer are formed and the target substrate.

2. The deposition device of claim 1, wherein the source substrate and the target substrate are disposed in the vicinity of each other by less than several tens μm.

3. The deposition device of claim 1, further comprising a resistance measuring unit provided in one side of the deposition device to be electrically connected to the conductive layer.

4. The deposition device of claim 1, further comprising a heat generation temperature measuring unit provided in one side of the deposition device and measuring a heat generation temperature of the conductive layer.

5. The deposition device of claim 1, further comprising a source substrate cleaner.

6. The deposition device of claim 3, wherein further comprising a source substrate cleaner.

7. A deposition method using Joule heating, comprising:
forming a deposition target layer on the one surface of the source substrate to cover the conductive layer, a conductive layer being formed on one surface of the source substrate as a pattern to be deposited;
fixing the source substrate to a source substrate fixture, and fixing the target substrate to a target substrate fixture, and disposing the target substrate fixture and the source substrate fixture while facing the target substrate fixture and the source substrate fixture;
applying power to the conductive layer to heat-generate the conductive layer; and
evaporating and depositing a deposition target layer located at one surface of the conductive layer facing the target substrate to the target substrate by heat-generating the conductive layer.

8. The method of claim 7, wherein the source substrate and the target substrate are disposed to face the source substrate and the target substrate in a chamber in a vacuum state.

9. The method of claim 7, further electrically connecting the conductive layer and a resistance measuring unit to each other to measure resistance of the conductive layer before the applying power to the conductive layer.

10. The method of claim 7, further comprising measuring a heat generation temperature of the conductive layer when the applying power to the conductive layer to heat-generate the conductive layer.

11. The method of claim 7, further comprising moving the source substrate to a source substrate cleaner to clean an organic material remaining on the source substrate after the evaporating and depositing of the deposition target layer.

12. The method of claim 11, further comprising performing the steps of claim 7 on the cleaned source substrate after the cleaning of the organic material remaining on the source substrate cleaner.

13. The method of claim 7, further comprising moving the source substrate to a source substrate cleaner to clean an organic material remaining on the source substrate after the evaporating and depositing of the deposition target layer.

14. The method of claim 13, further comprising performing the steps of claim 7 on the cleaned source substrate after the cleaning of the organic material remaining on the source substrate cleaner.
